(19) United States
(12) Patent Application Publication
(10) Pub. No.: US 2025/0088189 A1
(43) Pub. Date: Mar. 13, 2025

(54) PULL-DOWN CIRCUIT, PULL-UP CIRCUIT, AND VOLTAGE SUPPLY CIRCUIT INCLUDING PULL-DOWN CIRCUIT AND PULL-UP CIRCUIT

(71) Applicant: SK hynix Inc., Gyeonggi-do (KR)

(72) Inventors: Junghan LEE, Gyeonggi-do (KR); Jin Seok LEE, Gyeonggi-do (KR)

(21) Appl. No.: 18/809,330

(22) Filed: Aug. 20, 2024

(30) Foreign Application Priority Data
Sep. 12, 2023 (KR) 10-2023-0121085

(51) Int. Cl. H03K 19/0185; H02M 3/07

(52) U.S. Cl. CPC H03K 19/018521; H02M 3/07

(57) ABSTRACT

A pull-down circuit and a pull-up circuit for using various voltages, and a voltage supply circuit including the pull-down circuit and the pull-up circuit are disclosed. The pull-up circuit includes a sink circuit configured to receive a charge pump voltage from a charge pump circuit and pull up the charge pump voltage of the charge pump circuit to a ground voltage, wherein the charge pump voltage is less than the ground voltage, and a level shifter configured to generate a level shifter output voltage and a one-shot signal in response to a charge pump enable signal controlling the charge pump circuit wherein the level shifter output voltage controls the sink circuit, and the one-shot signal prevents floating of a node through which the level shifter output voltage is output.

### CROSS-REFERENCE TO RELATED APPLICATION

This patent application claims the priority and benefits of Korean patent application No. 10-2023-0121085, filed on Sep. 12, 2023, the disclosure of which is incorporated herein by reference in its entirety.

### TECHNICAL FIELD

The technology and embodiments disclosed in the present disclosure generally relate to a pull-down circuit and a pull-up circuit for using various voltages, and a voltage supply circuit including the pull-down circuit and the pull-up circuit.

### BACKGROUND

An electronic device may generate various voltages to operate internal components thereof, and may supply the generated voltages to the internal components. The electronic device may use a charge pump circuit that generates various voltages by converting an input voltage into an output voltage greater than the input voltage or by converting the input voltage into an output voltage less than the input voltage.

The charge pump circuit may be activated or deactivated by an external control signal. The activated charge pump circuit may output an adjusted output voltage that is greater or less than an input voltage thereof. The deactivated charge pump circuit may output an output voltage equal to an input voltage thereof. However, due to such characteristics of the charge pump circuit, it may be difficult for the charge pump circuit to be immediately switched (transitioned) from the adjusted output voltage to the output voltage equal to the input voltage. Due to occurrence of such delay in voltage transition, a constituent component for receiving the output voltage within the charge pump circuit might not normally operate. In order to address such issues of the charge pump circuit, circuits (e.g., a pull-up circuit and a pull-down circuit) for supporting level shifting (or level switching) of the output voltage may be additionally used.

### SUMMARY

In accordance with an embodiment of the present disclosure, a pull-up circuit may include a sink circuit configured to receive a charge pump voltage from a charge pump circuit and pull up the charge pump voltage of the charge pump circuit to a ground voltage, wherein the charge pump voltage is less than the ground voltage, and a level shifter configured to generate a level shifter output voltage a one-shot signal in response to a charge pump enable signal controlling the charge pump circuit, wherein the level shifter output voltage controls the sink circuit, and the one-shot signal prevents floating of a node through which the level shifter output voltage is output.

In accordance with another embodiment of the present disclosure, a pull-down circuit may include a sink circuit configured to receive a charge pump voltage from a charge pump circuit and pull down the charge pump voltage of the charge pump circuit to a power-supply voltage, wherein the charge pump voltage is greater than the power-supply voltage, and a level shifter configured to generate a level shifter output voltage and a one-shot signal in response to a charge pump enable signal controlling the charge pump circuit, wherein the level shifter output voltage controls the sink circuit, and the one-shot signal prevents floating of a node through which the level shifter output voltage is output.

In accordance with another embodiment of the present disclosure, a voltage supply circuit may include a charge pump circuit configured to amplify a power-supply voltage or a ground voltage to generate an output signal in response to a charge pump enable signal, and a voltage adjusting circuit coupled to a sink circuit, and configured to generate a level shifter output voltage and a one-shot signal in response to the charge pump enable signal, wherein the level shifter output voltage controls the sink circuit that pulls up or pulls down the output signal of the charge pump circuit, and the one-shot signal prevents floating of a node through which the level shifter output voltage is output.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating a voltage supply circuit based on some embodiments of the present disclosure.

FIG. 2 is a timing diagram illustrating an operation of the voltage supply circuit shown in FIG. 1 based on some embodiments of the present disclosure.

FIG. 3 is a block diagram illustrating a pull-down circuit or a pull-up circuit shown in FIG. 1 based on some embodiments of the present disclosure.

FIG. 4 is a circuit diagram illustrating a pull-up circuit serving as a voltage adjusting circuit shown in FIG. 3 based on some embodiments of the present disclosure.

FIG. 5 is a circuit diagram illustrating a non-overlap signal generator shown in FIG. 4 based on some embodiments of the present disclosure.

FIG. 6 is a circuit diagram illustrating a one-shot signal generator shown in FIG. 4 based on some embodiments of the present disclosure.

FIG. 7 is a timing diagram illustrating an operation of the pull-up circuit shown in FIG. 4 based on some embodiments of the present disclosure.

FIG. 8 is a circuit diagram illustrating a pull-down circuit serving as the voltage adjusting circuit shown in FIG. 3 based on some embodiments of the present disclosure.

FIG. 9 is a circuit diagram illustrating a non-overlap signal generator shown in FIG. 8 based on some embodiments of the present disclosure.

FIG. 10 is a circuit diagram illustrating a one-shot signal generator shown in FIG. 8 based on some embodiments of the present disclosure.

FIG. 11 is a timing diagram illustrating an operation of the pull-down circuit shown in FIG. 8 based on some embodiments of the present disclosure.

### DETAILED DESCRIPTION

The embodiments of the present disclosure provide a pull-down circuit and a pull-up circuit for using various voltages, and a voltage supply circuit including the same, that may be used in configurations to substantially address one or more technical or engineering issues and to mitigate limitations or disadvantages encountered in some other circuits. Some embodiments of the present disclosure relate to a pull-down circuit and a pull-up circuit capable of guaranteeing stable operation, and a voltage supply circuit including the pull-down circuit and the pull-up circuit. In recognition of the issues above, the pull-down circuit or the pull-up circuit based on some embodiments of the present disclosure can stably operate within a range that does not deviate from a breakdown voltage of transistors included in the pull-down or pull-up circuit.

Reference will now be made in detail to the embodiments of the present disclosure which are illustrated in the accompanying drawings. Wherever possible, the same reference numbers will be used throughout the drawings to refer to the same or like parts. While this disclosure is susceptible to various modifications and alternative forms, specific embodiments thereof are shown by way of example in the drawings. However, this disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the present disclosure may provide a variety of effects capable of being directly or indirectly recognized through the disclosed technology.

Various embodiments of the present disclosure relate to a pull-down circuit and a pull-up circuit capable of guaranteeing stable operation, and a voltage supply circuit including the pull-down circuit and the pull-up circuit.

It is to be understood that both the foregoing general description and the following detailed description of the disclosed technology are illustrative, descriptive, and are intended to provide further description of the embodiments of the present disclosure as claimed.

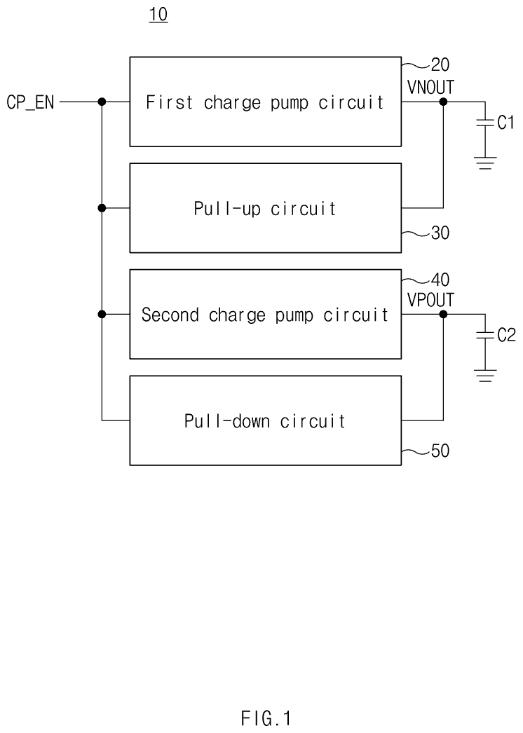

FIG. 1 is a block diagram illustrating a voltage supply circuit 10 based on some embodiments of the present disclosure.

Referring to FIG. 1, the voltage supply circuit 10 may generate a plurality of power voltages and a plurality of ground voltages. Further, the voltage supply circuit 10 may supply the plurality of power voltages and the plurality of ground voltages to terminals included in an electronic device that requires the corresponding power voltage or ground voltage among the plurality of power voltages and the plurality of ground voltages. For example, the electronic device may be implemented as an application processor, a memory device, an image sensing device, or a communication device, but other implementations are also possible.

For example, when the electronic device is the image sensing device, the voltage supply circuit 10 may supply a voltage to at least one of a boosting circuit, a dual conversion gain (DCG) circuit, and a negative deep trench isolation (NDTI) bias voltage generation circuit. Here, the boosting circuit may perform voltage boosting to a high voltage to increase capacitance of a floating diffusion node that stores or accumulates photocharges generated by sensing light. The DCG circuit may change capacitance of the floating diffusion node to adjust a conversion gain within a pixel, and may thus acquire a high dynamic range (HDR) image. The NDTI bias voltage generation circuit may suppress dark current of a deep trench isolation (DTI) structure configured to optically isolate adjacent pixels from each other.

The voltage supply circuit 10 may include a first charge pump circuit 20, a pull-up circuit 30, a second charge pump circuit 40, and a pull-down circuit 50.

The first charge pump circuit 20 may generate a first charge pump voltage less than a ground voltage by boosting the ground voltage in response to a charge pump enable signal CP_EN.

Specifically, the first charge pump circuit 20 may generate a first charge pump voltage in response to a logic high level of the charge pump enable signal CP_EN, and may transmit the first charge pump voltage to a first output node VNOUT. The first charge pump circuit 20 may be deactivated in response to a logic low level of the charge pump enable signal CP_EN. For example, deactivation of the first charge pump circuit 20 may mean that the first charge pump circuit 20 is electrically isolated from the first output node VNOUT or stops operation thereof.

In some embodiments, the logic high level may refer to a power-supply voltage, and the logic low level may refer to the ground voltage.

The pull-up circuit 30 may perform a pull-up operation on the first output node VNOUT in response to the charge pump enable signal CP_EN. Here, the pull-up operation may refer to an operation of level-shifting a certain voltage to a higher voltage. Specifically, the pull-up circuit 30 may pull up the voltage of the first output node VNOUT from the first charge pump voltage to the ground voltage in response to a logic low level of the charge pump enable signal CP_EN. The pull-up circuit 30 may be deactivated in response to a logic high level of the charge pump enable signal CP_EN. For example, deactivation of the pull-up circuit 30 may mean that the pull-up circuit 30 is electrically isolated from the first output node VNOUT or stops operation thereof.

The first output node VNOUT may be connected to the first capacitor C1. In an embodiment, one terminal of the first capacitor C1 is connected to the ground terminal, and the other terminal of the first capacitor C1 is connected to the first output node VNOUT. The first capacitor C1 may provide a predetermined capacitance to maintain the voltage of the first output node VNOUT.

The second charge pump circuit 40 may generate a second charge pump voltage greater than the power-supply voltage by amplifying the power-supply voltage in response to the charge pump enable signal CP_EN. Specifically, the second charge pump circuit 40 may generate the second charge pump voltage in response to a logic high level of the charge pump enable signal CP_EN, and may output the second charge pump voltage to a second output node VPOUT. The second charge pump circuit 40 may be deactivated in response to a logic low level of the charge pump enable signal CP_EN. For example, deactivation of the second charge pump circuit 40 may mean that the second charge pump circuit 40 is electrically isolated from the second output node VPOUT or stops operation thereof.

The pull-down circuit 50 may perform a pull-down operation on the second output node VPOUT in response to the charge pump enable signal CP_EN. Here, the pull-down operation may refer to an operation of level-shifting a certain voltage to a lower voltage. Specifically, the pull-down circuit 50 may pull down the voltage of the second output node VPOUT from the second charge pump voltage to the power-supply voltage in response to a logic low level of the charge pump enable signal CP_EN. The pull-down circuit 50 may be deactivated in response to a logic high level of the charge pump enable signal CP_EN. For example, deactivation of the pull-down circuit 50 may mean that the pull-down circuit 50 is electrically isolated from the second output node VPOUT or stops operation thereof.

The second output node VPOUT may be connected to the second capacitor C2. In an embodiment, one terminal of the second capacitor C2 is connected to the ground terminal, and the other terminal of the second capacitor C2 is connected to the second output node VPOUT. The second capacitor C2 may provide a predetermined capacitance to maintain the voltage of the second output node VPOUT.

In some implementations, the power-supply voltage may be a default power-supply voltage (e.g., 2.8V), and the second charge pump voltage may be a boosted power-supply voltage (e.g., 2.9V to 4.3V). The ground voltage may be a default ground voltage (e.g., 0V), and the first charge pump voltage may be a boosted ground voltage (e.g., −1.25V to −3.5V).

Although FIG. 1 illustrates that the first charge pump circuit 20, the pull-up circuit 30, the second charge pump circuit 40, and the pull-down circuit 50 are controlled by the same charge pump enable signal CP_EN, other embodiments are also possible. In some other embodiments, the first charge pump circuit 20 and the pull-up circuit 30 may be controlled by an independent charge pump enable signal different from the charge pump enable signal that controls the second charge pump circuit 40 and the pull-down circuit 50.

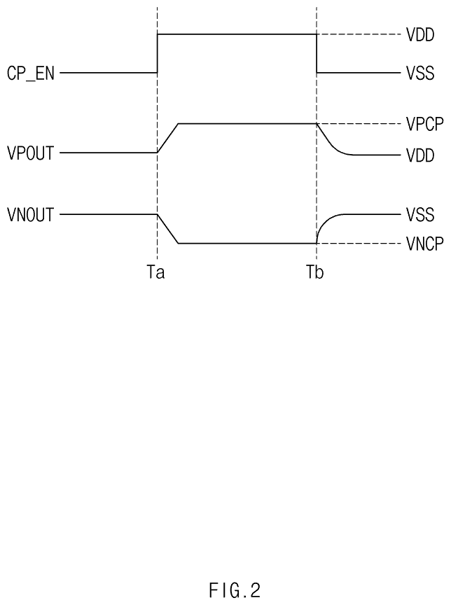

FIG. 2 is a timing diagram illustrating an operation of the voltage supply circuit 10 shown in FIG. 1 based on some embodiments of the present disclosure.

Referring to FIG. 2, the voltage supply circuit 10 may output the power-supply voltage VDD or the second charge pump voltage VPCP to the second output node VPOUT in response to the charge pump enable signal CP_EN.

Before a time point Ta, the charge pump enable signal CP_EN may have a ground voltage VSS that is at a logic low level. Accordingly, the second output node VPOUT may have the power-supply voltage VDD due to a pull-down operation of the pull-down circuit 50.

At the time point Ta, the charge pump enable signal CP_EN may transition from the ground voltage VSS to the power-supply voltage VDD that is at a logic high level. Accordingly, the second charge pump circuit 40 may generate the second charge pump voltage VPCP in response to the power-supply voltage VDD of the charge pump enable signal CP_EN, and may output the second charge pump voltage VPCP to the second output node VPOUT. In this circumstance, the pull-down circuit 50 may be deactivated in response to the power-supply voltage VDD of the charge pump enable signal CP_EN.

At a time point Tb, the charge pump enable signal CP_EN may transition from the power-supply voltage VDD to the ground voltage VSS. Accordingly, the pull-down circuit 50 may pull down the voltage of the second output node VPOUT from the second charge pump voltage VPCP to the power-supply voltage VDD in response to the ground voltage VSS of the charge pump enable signal CP_EN. In this circumstance, the second charge pump circuit 40 may be deactivated in response to the ground voltage VSS of the charge pump enable signal CP_EN.

The voltage supply circuit 10 may output to the first output node VNOUT the ground voltage VSS or the first charge pump voltage VNCP in response to the charge pump enable signal CP_EN.

Before the time point Ta, the charge pump enable signal CP_EN may have a ground voltage VSS that is at a logic low level. Accordingly, the first output node VNOUT may have the ground voltage VSS due to a pull-up operation of the pull-up circuit 30.

At the time point Ta, the charge pump enable signal CP_EN may transition from the ground voltage VSS to the power-supply voltage VDD. Accordingly, the first charge pump circuit 20 may generate the first charge pump voltage VNCP in response to the power-supply voltage VDD of the charge pump enable signal CP_EN, and may output the first charge pump voltage VNCP to the first output node VNOUT. In this circumstance, the pull-up circuit 30 may be deactivated in response to the power-supply voltage VDD of the charge pump enable signal CP_EN.

At the time point Tb, the charge pump enable signal CP_EN may transition from the power-supply voltage VDD to the ground voltage VSS. Accordingly, the pull-up circuit 30 may pull up the voltage of the first output node VNOUT from the first charge pump voltage VNCP to the ground voltage VSS in response to the ground voltage VSS of the charge pump enable signal CP_EN. In this circumstance, the first charge pump circuit 20 may be deactivated in response to the ground voltage VSS of the charge pump enable signal CP_EN.

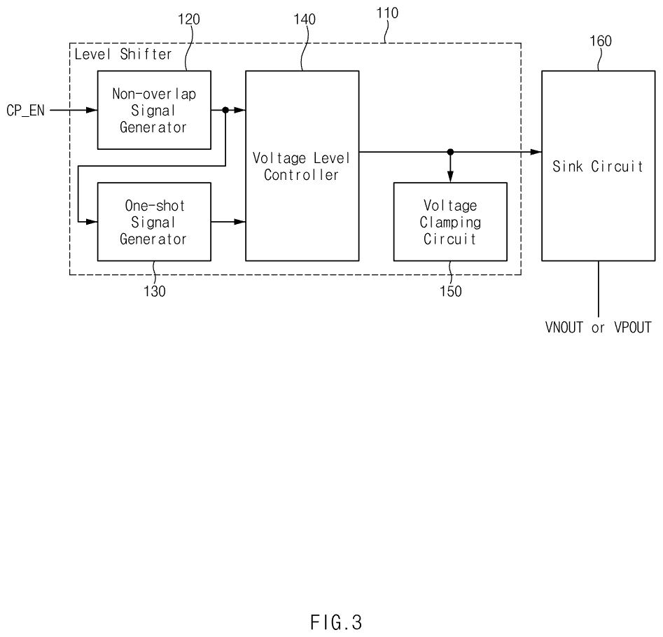

FIG. 3 is a block diagram illustrating the pull-up circuit 30 or the pull-down circuit 50 shown in FIG. 1 based on some embodiments of the present disclosure.

Referring to FIG. 3, the voltage adjusting circuit 100 may be a circuit that functionally represents the configuration of the pull-up circuit 30 or the pull-down circuit 50 shown in FIG. 1.

The voltage adjusting circuit 100 may include a level shifter 110 and a sink circuit 160. The level shifter 110 is configured to control the voltage level of either the first output node VNOUT or the second output node VPOUT in response to the charge pump enable signal CP_EN. The sink circuit 160 is configured to pull up or down the voltage level of either the first output node VNOUT or the second output node VPOUT.

The level shifter 110 may include a non-overlap signal generator 120, a one-shot signal generator 130, a voltage level controller 140, and a voltage clamping circuit 150.

The non-overlap signal generator 120 may generate at least two non-overlapping signals by delaying the charge pump enable signal CP_EN with different delay times. In some embodiments, two complementary transistors (e.g., a P-channel metal-oxide-semiconductor (PMOS) transistor and an N-channel metal-oxide-semiconductor (NMOS) transistor) included in the voltage level controller 140 may be designed to operate in response to the charge pump enable signal CP_EN. In this case, when two transistors are turned on and off at the same time point while being connected to the same node, there may occur a shoot-through current having the same effect as if two transistors were turned on simultaneously. Since the shoot-through current may cause serious damage to the electronic device, the non-overlap signal generator 120 may supply two non-overlapping signals obtained by delaying the charge pump enable signal CP_EN with different delay times to complementary transistors, respectively, so that the two transistors can be turned on and off at different time points.

The one-shot signal generator 130 may generate a one-shot signal to prevent floating of the output node of the level shifter 110 in response to a signal input to transistors included in the voltage level controller 140.

The voltage level controller 140 may generate a control signal for controlling the sink circuit 160 in response to the charge pump enable signal CP_EN, more specifically, in response to non-overlapping signals obtained by delaying the charge pump enable signal CP_EN. In addition, the voltage level controller 140 may prevent floating of the output node of the level shifter 110 by using the one-shot signal.

The voltage clamping circuit 150 may be connected to the output node of the level shifter 110 to limit a voltage level applied to the sink circuit 160 within a predetermined range. This is because, if the voltage level of the output node of the level shifter 110 exceeds the predetermined range, the sink circuit 160 may be damaged.

The sink circuit 160 may pull up or pull down a voltage level of either the first output node VNOUT or the second output node VPOUT according to a control signal transmitted to the output node of the level shifter 110. That is, the sink circuit 160 may pull up the output voltage of the first charge pump circuit 20 to the ground voltage VSS, or may pull down the output voltage of the second charge pump circuit 40 to the power-supply voltage VDD. The first charge pump circuit 20 may generate the first charge pump voltage VNCP less than the ground voltage VSS. The second charge pump circuit 40 may generate the second charge pump voltage VPCP greater than the power-supply voltage VDD.

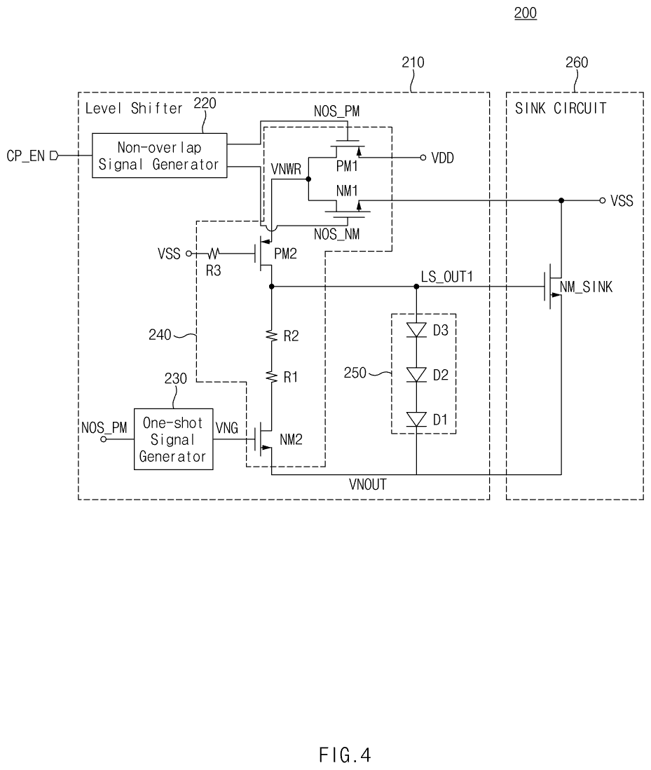

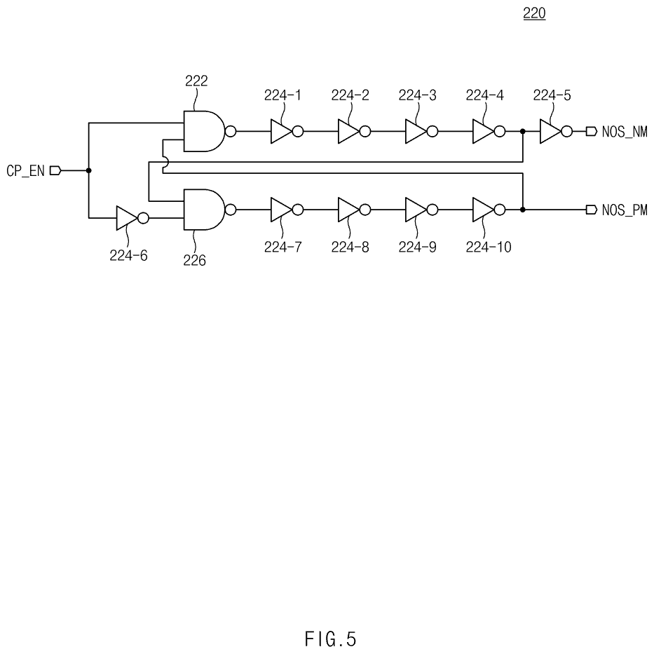

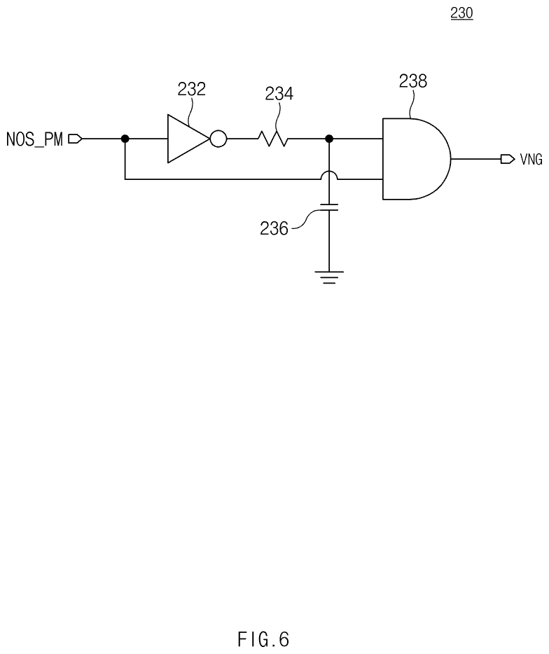

FIG. 4 is a circuit diagram illustrating the pull-up circuit 200 serving as the voltage adjusting circuit 100 shown in FIG. 3 based on some embodiments of the present disclosure. FIG. 5 is a circuit diagram illustrating the non-overlap signal generator 220 shown in FIG. 4 based on some embodiments of the present disclosure. FIG. 6 is a circuit diagram illustrating the one-shot signal generator 230 shown in FIG. 4 based on some embodiments of the present disclosure.

Referring to FIG. 4, the pull-up circuit 200 may correspond to the voltage adjusting circuit 100 of FIG. 3. The pull-up circuit 200 may include a level shifter 210 and a sink circuit 260. The level shifter 210 may have a function corresponding to the level shifter 110 of the voltage adjusting circuit 100 in FIG. 3, and the sink circuit 260 may have a function corresponding to the sink circuit 160 of the voltage adjusting circuit 100 in FIG. 3.

The level shifter 210 may include a non-overlap signal generator 220, a one-shot signal generator 230, a voltage level controller 240, and a voltage clamping circuit 250.

The non-overlap signal generator 220 may generate a first non-overlapping signal NOS_PM and a second non-overlapping signal NOS_NM by delaying the charge pump enable signal CP_EN with different delay times.

Referring to FIG. 5, the non-overlap signal generator 220 may include a first NAND gate 222, first to tenth inverters 224-1 to 224-10, and a second NAND gate 226.

The first NAND gate 222 may perform a NAND operation between the charge pump enable signal CP_EN and the first non-overlapping signal NOS_PM. To this end, the input terminal of the first NAND gate 222 may be connected to the output terminal of the tenth inverter 224-10.

The first to fifth inverters 224-1 to 224-5 may be connected in series between an output terminal of the first NAND gate 222 and an output terminal through which the second non-overlapping signal NOS_NM of the non-overlap signal generator 220 is output. Each of the first to fifth inverters 224-1 to 224-5 may invert an input signal thereof, and may output the inverted signal. Each of the first to fifth inverters 224-1 to 224-5 may delay the input signal by a predetermined delay time, and may thus output the delayed signal. Here, the operation of inverting the signal may mean that the power-supply voltage VDD is converted into the ground voltage VSS or the ground voltage VSS is converted into the power-supply voltage VDD.

The sixth inverter 224-6 may be connected between a terminal to which the charge pump enable signal CP_EN is input and an input terminal of the second NAND gate 226. The sixth inverter 224-6 may invert the charge pump enable signal CP_EN and thus output the inverted charge pump enable signal CP_EN.

The seventh to tenth inverters 224-7 to 224-10 may be connected in series between an output terminal of the second NAND gate 226 and an output terminal through which the first non-overlapping signal NOS_PM of the non-overlap signal generator 220 is output. Each of the seventh to tenth inverters 224-7 to 224-10 may invert an input signal thereof, and may output the inverted signal. Each of the sixth to tenth inverters 224-6 to 224-10 may delay the input signal by a predetermined delay time, and may thus output the delayed signal.

The second NAND gate 226 may perform a NAND operation between the inverted charge pump enable signal CP_EN and an input signal that is input to the fifth inverter 224-5 configured to output the second non-overlapping signal, and may output the resultant signal. To this end, the input terminal of the second NAND gate 226 may be connected to the input terminal of the fifth inverter 224-5.

The first NAND gate 222 and the first to fifth inverters 224-1 to 224-5 may constitute a first path. The charge pump enable signal CP_EN may be output as the second non-overlapping signal NOS_NM through the first path. The second NAND gate 226 and the sixth to tenth inverters 224-6 to 224-10 may constitute a second path. The charge pump enable signal CP_EN may be output as the first non-overlapping signal NOS_PM through the second path. Although each of the first path and the second path is illustrated as including five inverters, the scope of the embodiments of the present disclosure is not limited thereto, and the number of inverters included in each path may be experimentally determined to be any odd number from among odd numbers.

Although each of the first non-overlapping signal NOS_PM and the second non-overlapping signal NOS_NM may have the same voltage level as the voltage level of the charge pump enable signal CP_EN after a predetermined delay time has elapsed, other embodiments are also possible, and it should be noted that the first non-overlapping signal NOS_PM and the second non-overlapping signal NOS_NM require different delay times to reach the same voltage level as the voltage level of the charge pump enable signal CP_EN.

For example, when the charge pump enable signal CP_EN transitions from the power-supply voltage VDD to the ground voltage VSS, the output signal of the first NAND gate 222 may immediately transition from the ground voltage VSS to the power-supply voltage VDD. After the delay time corresponding to the first to fifth inverters 224-1 to 224-5 has elapsed, the second non-overlapping signal NOS_NM may transition from the power-supply voltage VDD to the ground voltage VSS. Even when the charge pump enable signal CP_EN transitions from the power-supply voltage VDD to the ground voltage VSS, the output signal of the second NAND gate 226 may not change immediately, and the output signal of the second NAND gate 226 may transition from the power-supply voltage VDD to the ground voltage VSS at a time point where the output signal of the fourth inverter 224-4 transitions from the ground voltage VSS to the power-supply voltage VDD. Subsequently, after lapse of a delay time corresponding to the seventh to tenth inverters 224-7 to 224-10, the first non-overlapping signal NOS_PM may transition from the power-supply voltage VDD to the ground voltage VSS.

In another embodiment, when the charge pump enable signal CP_EN transitions from the ground voltage VSS to the power-supply voltage VDD, the output signal of the second NAND gate 226 may immediately transition from the ground voltage VSS to the power-supply voltage VDD. After the delay time corresponding to the seventh to tenth inverters 224-7 to 224-10 has elapsed, the first non-overlapping signal NOS_PM may transition from the ground voltage VSS to the power-supply voltage VDD. Even when the charge pump enable signal CP_EN transitions from the power-supply voltage VDD to the ground voltage VSS, the output signal of the first NAND gate 222 may not change immediately, and the output signal of the first NAND gate 222 may transition from the power-supply voltage VDD to the ground voltage VSS at a time point where the output signal of the tenth inverter 224-10 transitions from the ground voltage VSS to the power-supply voltage VDD. Subsequently, after lapse of a delay time corresponding to the first to fifth inverters 224-1 to 224-5, the second non-overlapping signal NOS_NM may transition from the ground voltage VSS to the power-supply voltage VDD.

Referring again to FIG. 4, the one-shot signal generator 230 may generate a one-shot signal VNG to prevent floating of the output node of the level shifter 210 in response to the first non-overlapping signal NOS_PM acting as a gate voltage of a first PMOS transistor PM1.

Referring to FIG. 6, the one-shot signal generator 230 may include a one-shot inverter 232, a one-shot resistor 234, a one-shot capacitor 236, and an AND gate 238.

The one-shot inverter 232 may invert the first non-overlapping signal NOS_PM, and may output the inverted first non-overlapping signal. The input terminal of the one-shot inverter 232 may be connected to a terminal to which the first non-overlapping signal NOS_PM is input, and an output terminal of the one-shot inverter 232 may be connected to the one-shot resistor 234.

The one-shot resistor 234 may be connected between the output terminal of the one-shot inverter 232 and the input terminal of the AND gate 238. The one-shot capacitor 236 may be connected between the input terminal of the AND gate 238 and the ground terminal. The one-shot resistor 234 and the one-shot capacitor 236 may electrically stabilize the voltage of the input terminal of the AND gate 238.

The AND gate 238 may perform an AND operation between the inverted first non-overlapping signal NOS_PM received from the one-shot resistor 234 and the first non-overlapping signal NOS_PM, and may output the resultant signal. To this end, the input terminals of the AND gate 238 may be connected to the one-shot resistor 234 and the terminal through which the first non-overlapping signal NOS_PM is received, respectively.

In a time section where the first non-overlapping signal NOS_PM is at the ground voltage VSS, the ground voltage VSS may be applied to one input terminal of the AND gate 238, so that the one-shot signal generator 230 may generate the ground voltage VSS as the one-shot signal VNG. At this time, the power-supply voltage VDD may be applied to the other input terminal of the AND gate 238.

When the first non-overlapping signal NOS_PM transitions from the ground voltage VSS to the power-supply voltage VDD, the power-supply voltage VDD may be applied to one input terminal of the AND gate 238, and the other input terminal of the AND gate 238 may temporarily maintain the power-supply voltage VDD due to the one-shot inverter 232. Accordingly, the one-shot signal generator 230 may output the power-supply voltage VDD as the one-shot signal VNG.

The first non-overlapping signal NOS_PM of the power-supply voltage VDD may be delayed and inverted by the one-shot inverter 232 and then transmitted to a destination. Accordingly, the other input terminal of the AND gate 238 may have a ground voltage VSS, and the one-shot signal generator 230 may output the ground voltage VSS as a one-shot signal VNG.

Referring again to FIG. 4, the voltage level controller 240 may include a first PMOS transistor PM1, a first NMOS transistor NM1, a second PMOS transistor PM2, a second NMOS transistor NM2, and first to third PMOS resistors (R1-R3).

The first PMOS transistor PM1 may be a PMOS transistor that is connected between a common node VNWR and a terminal to which the power-supply voltage VDD is input and includes a gate to which the first non-overlapping signal NOS_PM is input. The first PMOS transistor PM1 may be turned on in response to the first non-overlapping signal NOS_PM of the ground voltage VSS. The power-supply voltage VDD may be transmitted to the common node VNWR through the turned-on first PMOS transistor PM1. The first PMOS transistor PM1 may be turned off in response to the first non-overlapping signal NOS_PM of the power-supply voltage VDD.

The first NMOS transistor NM1 may be an NMOS transistor that is connected between a common node VNWR and a terminal to which the ground voltage VSS is input and includes a gate to which the second non-overlapping signal NOS_NM is input. The first NMOS transistor NM1 may be turned on in response to the second non-overlapping signal NOS_NM of the power-supply voltage VDD. The ground voltage VSS may be transmitted to the common node VNWR through the turned-on first NMOS transistor NM1. The first NMOS transistor NM1 may be turned off in response to the second non-overlapping signal NOS_NM of the ground voltage VSS.

The second PMOS transistor PM2 may be a PMOS transistor that is connected between the common node VNWR and a node through which a first level shifter output voltage LS_OUT1 is output and includes a gate where the ground voltage VSS is received through the third resistor R3. The second PMOS transistor PM2 may be turned on by the power-supply voltage VDD on the common node VNWR. The turned-on second PMOS transistor PM2 may transmit the power-supply voltage VDD to the node through which the first level shifter output voltage LS_OUT1 is output. The second PMOS transistor PM2 may be turned off by the ground voltage VSS on the common node VNWR.

The second NMOS transistor NM2 may be an NMOS transistor that is connected between the first resistor R1 and the first output node VNOUT and includes a gate to which the one-shot signal VNG is input. The second NMOS transistor NM2 may be turned on in response to the one-shot signal VNG of the power-supply voltage VDD. The turned-on second NMOS transistor NM2 may output the voltage of the first output node VNOUT to the node through which the first level shifter output voltage LS_OUT1 is output. The second NMOS transistor NM2 may be turned off in response to the one-shot signal VNG of the ground voltage VSS.

The first resistor R1 and the second resistor R2 may be connected in series between the output node of the first level shifter output voltage LS_OUT1 and the second NMOS transistor NM2. The first resistor R1 and the second resistor R2 may allow the voltage of the common node VNWR to be transferred to the output node of the first level shifter output voltage LS_OUT1 without being affected by the second NMOS transistor NM2. Although FIG. 4 illustrates that two resistors R1, R2 are connected between the second NMOS transistor NM2 and the output node of the first level shifter output voltage LS_OUT1, other embodiments are also possible, and it should be noted that the number of resistors and a resistance value of each resistor can be determined experimentally.

The third resistor R3 may be connected between a gate of the second PMOS transistor PM2 and an input terminal of the ground voltage VSS. The third resistor R3 may be a protection circuit to prevent damage to the second PMOS transistor PM2 due to electrostatic discharge ESD that may be introduced from the input terminal of the ground voltage VSS.

The voltage clamping circuit 250 may be connected to an output node of the first level shifter output voltage LS_OUT1 and the first output node VNOUT. The output node of the first level shifter output voltage LS_OUT1 may be connected to a gate of the sink transistor NM_SINK of the sink circuit 260. The first output node VNOUT may be connected to a source of the sink transistor NM_SINK. The voltage clamping circuit 250 may refer to a protection circuit that limits a voltage between two nodes so that a gate-source voltage of the sink transistor NM_SINK does not exceed a breakdown voltage of the sink transistor NM_SINK.

In the embodiment of FIG. 4, the voltage clamping circuit 250 is implemented with first to third diodes D1-D3 connected in series to each other, but the embodiment is not limited thereto, and the number and type of diodes may be experimentally determined in consideration of the breakdown voltage of the sink transistor NM_SINK.

The sink circuit 260 may include a sink transistor NM_SINK that pulls up the voltage level of the first output node VNOUT in response to the first level shifter output voltage LS_OUT1 applied to the output node of the level shifter 210.

The sink transistor NM_SINK may be an NMOS transistor that is connected between a terminal for the ground voltage VSS and the first output node VNOUT and includes a gate to which the first level shifter output voltage LS_OUT1 is input. The sink transistor NM_SINK may be turned on in response to the first level shifter output voltage LS_OUT1 of the power-supply voltage VDD. Alternatively, if the sink transistor NM_SINK is implemented with a PMOS transistor, the sink transistor NM_SINK may be turned on in response to the ground voltage VSS. The turned-on sink transistor NM_SINK may output the ground voltage VSS to the first output node VNOUT. The sink transistor NM_SINK may be turned off in response to the first level shifter output voltage LS_OUT1 of the first charge pump voltage VNCP.

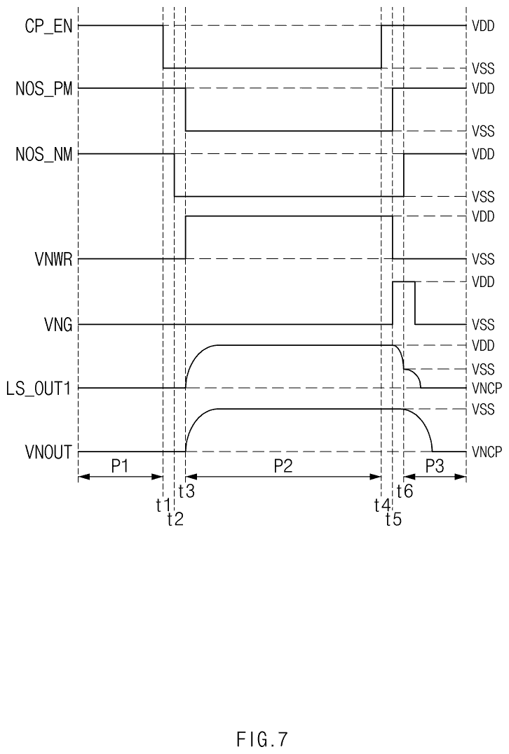

FIG. 7 is a timing diagram illustrating an operation of the pull-up circuit shown in FIG. 4 based on some embodiments of the present disclosure.

Referring to FIGS. 4 to 7, the charge pump enable signal CP_EN maintains the power-supply voltage VDD, transitions to the ground voltage VSS at a first time point t1, and transitions back to the power-supply voltage VDD at a fourth time point t4.

In a first section P1 located before the first time point t1, each of the charge pump enable signal CP_EN, the first non-overlapping signal NOS_PM, and the second non-overlapping signal NOS_NM may have the power-supply voltage VDD. Accordingly, the first PMOS transistor PM1 may be turned off and the first NMOS transistor NM1 may be turned on.

The common node VNWR may receive the ground voltage VSS through the turned-on first NMOS transistor NM1, and may thus have the ground voltage VSS. Accordingly, the second PMOS transistor PM2 may be turned off.

Since the first non-overlapping signal NOS_PM maintains the power-supply voltage VDD, the one-shot signal VNG may have the ground voltage VSS. In addition, due to the operation of the first charge pump circuit 20, the first output node VNOUT may have the first charge pump voltage VNCP. Accordingly, the second NMOS transistor NM2 may be turned on, so that the first level shifter output voltage LS_OUT1 may have the first charge pump voltage VNCP. As a result, the sink transistor NM_SINK may remain turned off.

When the charge pump enable signal CP_EN transitions from the power-supply voltage VDD to the ground voltage VSS at the first time point t1, the first non-overlapping signal NOS_PM may transition to the ground voltage VSS at a third time point t3 by the operation of the non-overlap signal generator 220, and the second non-overlapping signal NOS_NM may transition to the ground voltage VSS at a second time point t2.

At the second time point t2, when the second non-overlapping signal NOS_NM transitions to the ground voltage VSS, the first NMOS transistor NM1 may be turned off so that the common node VNWR can be floated.

At the third time point t3, when the first non-overlapping signal NOS_PM transitions to the ground voltage VSS, the first PMOS transistor PM1 may be turned on so that the common node VNWR may have the power-supply voltage VDD. Accordingly, the second PMOS transistor PM2 may be turned on and the first level shifter output voltage LS_OUT1 may transition to the power-supply voltage VDD. As a result, the sink transistor NM_SINK may be turned on and the voltage of the first output node VNOUT may transition (i.e., may be pulled up) to the ground voltage VSS.

In this time point, the one-shot signal VNG may maintain the ground voltage VSS, and the second NMOS transistor NM2 may be turned off. As a result, the first level shifter output voltage LS_OUT1 can maintain the power-supply voltage VDD.

In a second section P2, each signal and the voltage of each node can be maintained.

When the charge pump enable signal CP_EN transitions from the ground voltage VSS to the power-supply voltage VDD at a fourth time point t4, the first non-overlapping signal NOS_PM may transition to the power-supply voltage VDD at a fifth time point t5 by the operation of the non-overlap signal generator 220, and the second non-overlapping signal NOS_NM may transition to the power-supply voltage VDD at a sixth time point t6.

When the first non-overlapping signal NOS_PM transitions to the power-supply voltage VDD at the fifth time point t5, the first PMOS transistor PM1 may be turned off so that the common node VNWR can be floated. In addition, as the first non-overlapping signal NOS_PM transitions to the power-supply voltage VDD, the one-shot signal VNG may transition to the power-supply voltage VDD and the second NMOS transistor NM2 may be turned on, so that the first level shifter output voltage LS_OUT1 may transition to the ground voltage VSS acting as the voltage of the first output node VNOUT.

When the second non-overlapping signal NOS_NM transitions to the power-supply voltage VDD at a sixth time point t6, the first NMOS transistor NM1 may be turned on so that the common node VNWR may have the ground voltage VSS. Accordingly, the second PMOS transistor PM2 may be turned off so that the first level shifter output voltage LS_OUT1 can be electrically isolated from the common node VNWR.

In addition, due to the operation of the first charge pump circuit 20, the first output node VNOUT may transition to the first charge pump voltage VNCP. Due to the turned-on second NMOS transistor NM2, the first level shifter output voltage LS_OUT1 may also transition to the first charge pump voltage VNCP in response to the voltage of the first output node VNOUT. As a result, the sink transistor NM_SINK may be turned off so that the first output node VNOUT can be electrically isolated from the ground voltage VSS.

In a subsequent third section P3, each signal and the voltage of each node can be maintained.

According to the method of operating the pull-up circuit 200, the transistors PM1, NM1, PM2, NM2, NM_SINK included in the pull-up circuit 200 may operate stably within a range that does not exceed the breakdown voltage (e.g., 3.8V).

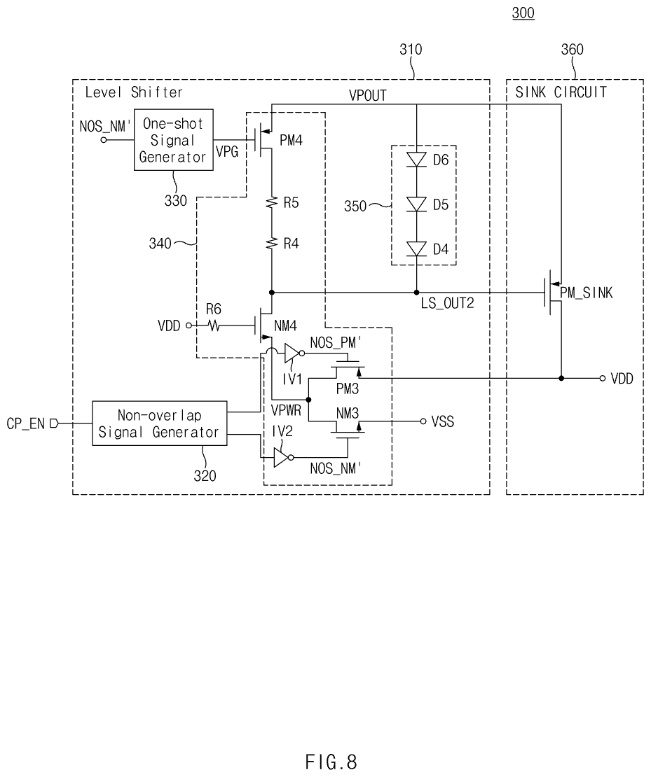

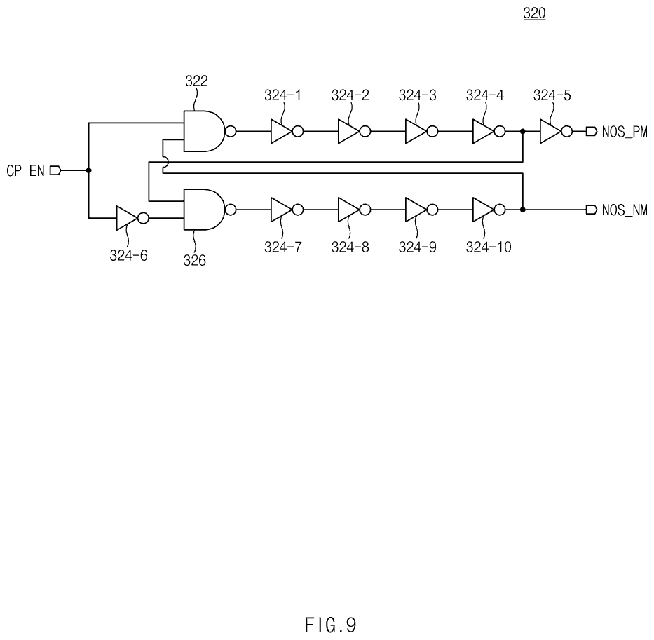

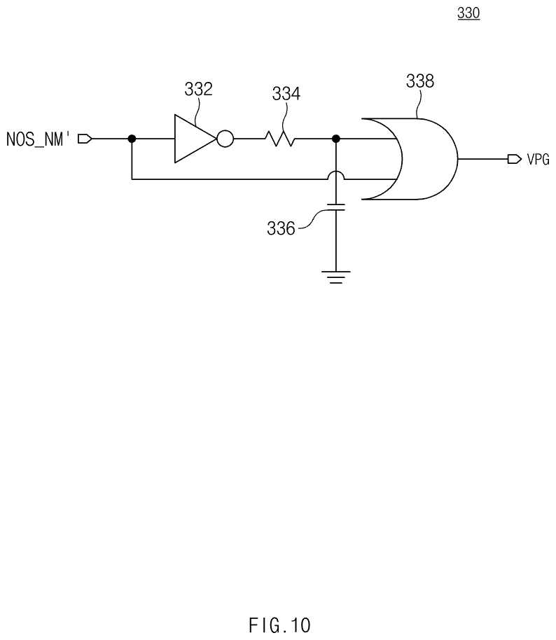

FIG. 8 is a circuit diagram illustrating the pull-down circuit 300 serving as the voltage adjusting circuit 100 shown in FIG. 3 based on some embodiments of the present disclosure. FIG. 9 is a circuit diagram illustrating the non-overlap signal generator 320 shown in FIG. 8 based on some embodiments of the present disclosure. FIG. 10 is a circuit diagram illustrating the one-shot signal generator 330 shown in FIG. 8 based on some embodiments of the present disclosure.

Referring to FIG. 8, the pull-down circuit 300 may correspond to another embodiment of the voltage adjusting circuit 100 of FIG. 3. The pull-down circuit 300 may include a level shifter 310 and a sink circuit 360. The level shifter 310 may have a function corresponding to the level shifter 110 of the voltage adjusting circuit 100. The sink circuit 360 may have a function corresponding to the sink circuit 160 of the voltage adjusting circuit 100.

The level shifter 310 may include a non-overlap signal generator 320, a one-shot signal generator 330, a voltage level controller 340, and a voltage clamping circuit 350.

The non-overlap signal generator 320 may generate a first non-overlapping signal NOS_PM and a second non-overlapping signal NOS_NM by delaying the charge pump enable signal CP_EN with different delay times.

Referring to FIG. 9, the non-overlap signal generator 320 may include a first NAND gate 322, first to tenth inverters (324-1 to 324-10, and a second NAND gate 326. Operations of the first NAND gate 322, the first to tenth inverters 324-1 to 324-10, and the second NAND gate 326 shown in FIG. 9 are substantially the same as operations of the first NAND gate 222, the first to tenth inverters 224-1 to 224-10, and the second NAND gate 226, respectively, and as such redundant description thereof will herein be omitted for brevity.

The first NAND gate 322 and the first to fifth inverters 324-1 to 324-5 may constitute a first path. The charge pump enable signal CP_EN may be output as the first non-overlapping signal NOS_PM through the first path. The second NAND gate 326 and the sixth to tenth inverters 324-6 to 324-10 may constitute a second path. The charge pump enable signal CP_EN may be output as the second non-overlapping signal NOS_NM through the second path. Although each of the first path and the second path is illustrated as including five inverters, the embodiments of the present disclosure are not limited thereto, and the number of inverters included in each path may be experimentally determined to be any odd number from among odd numbers.

Although the first non-overlapping signal NOS_PM and the second non-overlapping signal NOS_NM may have the same voltage level as the voltage level of the charge pump enable signal CP_EN after a predetermined delay time has elapsed, other embodiments are also possible, and it should be noted that the first non-overlapping signal NOS_PM and the second non-overlapping signal NOS_NM require different delay times to reach the same voltage level as the voltage level of the charge pump enable signal CP_EN.

For example, when the charge pump enable signal CP_EN transitions from the power-supply voltage VDD to the ground voltage VSS, the output signal of the first NAND gate 322 may immediately transition from the ground voltage VSS to the power-supply voltage VDD. After the delay time corresponding to the first to fifth inverters 324-1 to 324-5 has elapsed, the first non-overlapping signal NOS_PM may transition from the power-supply voltage VDD to the ground voltage VSS. Even when the charge pump enable signal CP_EN transitions from the power-supply voltage VDD to the ground voltage VSS, the output signal of the second NAND gate 326 may not change immediately, and the output signal of the second NAND gate 326 may transition from the power-supply voltage VDD to the ground voltage VSS at a time point where the output signal of the fourth inverter 324-4 transitions from the ground voltage VSS to the power-supply voltage VDD. Subsequently, after lapse of a delay time corresponding to the seventh to tenth inverters 324-7 to 324-10, the second non-overlapping signal NOS_NM may transition from the power-supply voltage VDD to the ground voltage VSS.

In another embodiment, when the charge pump enable signal CP_EN transitions from the ground voltage VSS to the power-supply voltage VDD, the output signal of the second NAND gate 326 may immediately transition from the ground voltage VSS to the power-supply voltage VDD. After the delay time corresponding to the seventh to tenth inverters 324-7 to 324-10 has elapsed, the second non-overlapping signal NOS_NM may transition from the ground voltage VSS to the power-supply voltage VDD. Even when the charge pump enable signal CP_EN transitions from the power-supply voltage VDD to the ground voltage VSS, the output signal of the first NAND gate 322 may not change immediately, and the output signal of the first NAND gate 322 may transition from the power-supply voltage VDD to the ground voltage VSS at a time point where the output signal of the tenth inverter 324-10 transitions from the ground voltage VSS to the power-supply voltage VDD. Subsequently, after lapse of a delay time corresponding to the first to fifth inverters 324-1 to 324-5, the first non-overlapping signal NOS_PM may transition from the ground voltage VSS to the power-supply voltage VDD.

Referring again to FIG. 8, the one-shot signal generator 330 may generate a one-shot signal VPG to prevent floating of the output node of the level shifter 310 in response to the inverted second non-overlapping signal NOS_NM′ acting as a gate voltage of a third PMOS transistor NM3.

Referring to FIG. 10, the one-shot signal generator 330 may include a one-shot inverter 332, a one-shot resistor 334, a one-shot capacitor 336, and an OR gate 338.

The one-shot inverter 332 may invert the inverted second non-overlapping signal NOS_NM′, and may output the second non-overlapping signal. The input terminal of the one-shot inverter 332 may be connected to a terminal to which the inverted second non-overlapping signal NOS_NM′ is input, and an output terminal of the one-shot inverter 332 may be connected to the one-shot resistor 334.

The one-shot resistor 334 may be connected between the output terminal of the one-shot inverter 332 and the input terminal of the OR gate 338. The one-shot capacitor 336 may be connected between the input terminal of the OR gate 338 and the ground terminal. The one-shot resistor 334 and the one-shot capacitor 336 may electrically stabilize the voltage of the input terminal of the OR gate 338.

The OR gate 338 may perform an OR operation between the inversion resultant signal of the inverted second non-overlapping signal received from the one-shot resistor 334 and the inverted second non-overlapping signal NOS_NM′, and may output the resultant signal. To this end, the input terminals of the OR gate 338 may be connected to the one-shot resistor 334 and the terminal through which the inverted second non-overlapping signal NOS_NM′ is received, respectively.

In a time section where the second non-overlapping signal NOS_NM is at the ground voltage VSS, the power-supply voltage VDD may be applied to one input terminal of the OR gate 338, so that the one-shot signal generator 330 may generate the power-supply voltage VDD as the one-shot signal VPG. At this time, the ground voltage VSS may be applied to the other input terminal of the OR gate 338.

When the second non-overlapping signal NOS_NM transitions from the ground voltage VSS to the power-supply voltage VDD, the ground voltage VSS may be applied to one input terminal of the OR gate 338, and the other input terminal of the OR gate 338 may temporarily maintain the ground voltage VSS due to the one-shot inverter 332. Accordingly, the one-shot signal generator 330 may output the ground voltage VSS as the one-shot signal VPG.

The inverted second non-overlapping signal NOS_NM′ of the ground voltage VSS may be delayed and inverted by the one-shot inverter 332 and then transmitted to a destination. Accordingly, the other input terminal of the OR gate 338 may have the power-supply voltage VDD, and the one-shot signal generator 330 may output the power-supply voltage VDD as a one-shot signal VPG.

Referring again to FIG. 8, the voltage level controller 340 may include a first inverter IV1, a second inverter IV2, a third PMOS transistor PM3, a third NMOS transistor NM3, a fourth PMOS transistor PM4, a fourth NMOS transistor NM4, and fourth to sixth resistors R4-R6.

The first inverter IV1 may be connected between the non-overlap signal generator 320 and a gate of the third PMOS transistor PM3, may invert the first non-overlapping signal NOS_PM, and may output the inverted first non-overlapping signal NOS_PM′.

The second inverter IV2 may be connected between the non-overlap signal generator 320 and a gate of the third NMOS transistor NM3, may invert the second non-overlapping signal NOS_NM, and may output the inverted second non-overlapping signal NOS_NM′.

The third PMOS transistor PM3 may be a PMOS transistor that is connected between a common node VPWR and an input terminal of the power-supply voltage VDD and includes a gate to which the inverted first non-overlapping signal NOS_PM′ is input. The third PMOS transistor PM3 may be turned on in response to the inverted first non-overlapping signal NOS_PM′ acting as an inversion signal of the ground voltage VSS, and the power-supply voltage VDD may be turned on through the turned-on third PMOS transistor PM3. The third PMOS transistor PM3 may be turned off in response to the inverted first non-overlapping signal NOS_PM′ acting as an inversion signal of the power-supply voltage VDD.

The third NMOS transistor NM3 may be an NMOS transistor that is connected between a common node VPWR and an input terminal of the ground voltage VSS and includes a gate to which the inverted second non-overlapping signal NOS_NM′ is input. The third NMOS transistor NM3 may be turned on in response to the inverted second non-overlapping signal NOS_NM′ acting as an inversion signal of the power-supply voltage VDD, and the ground voltage VSS may be transmitted to the common node VPWR through the turned-on third NMOS transistor NM3. The third NMOS transistor NM3 may be turned off in response to the inverted second non-overlapping signal NOS_NM′ acting as an inversion signal of the ground voltage VSS.

The fourth NMOS transistor NM4 may be connected between the common node VPWR and the node through which a second level shifter output voltage LS_OUT2 is output and includes a gate through which the power-supply voltage VDD is received through a sixth resistor R6. The fourth NMOS transistor NM4 may be turned on by the common node VPWR having the ground voltage VSS. The turned-on fourth NMOS transistor NM4 may transmit the ground voltage VSS to the node through which the second level shifter output voltage LS_OUT2 is output. The fourth NMOS transistor NM4 may be turned off by the common node VPWR having the power-supply voltage VDD.

The fourth PMOS transistor PM4 may be a PMOS transistor that is connected between the fifth resistor R5 and the second output node VPOUT and includes a gate to which the one-shot signal VPG is input. The fourth PMOS transistor PM4 may be turned on in response to the one-shot signal VPG of the ground voltage VSS. The turned-on fourth PMOS transistor PM4 may output the voltage of the second output node VPOUT to the node through which the second level shifter output voltage LS_OUT2 is output. The fourth PMOS transistor PM4 may be turned off in response to the one-shot signal VPG of the power-supply voltage VDD.

The fourth resistor R4 and the fifth resistor R5 may be connected in series between the output node of the second level shifter output voltage LS_OUT2 and the fourth PMOS transistor PM4. The fourth resistor R4 and the fifth resistor R5 may allow the voltage of the common node VPWR to be transferred to the output node of the second level shifter output voltage LS_OUT2 without being affected by the fourth PMOS transistor PM4. Although FIG. 8 illustrates that two resistors R4, R5 are connected between the fourth PMOS transistor PM4 and the output node of the second level shifter output voltage LS_OUT2, other embodiments are also possible, and it should be noted that the number of resistors and a resistance value of each resistor can be determined experimentally.

The sixth resistor R6 may be connected between a gate of the fourth NMOS transistor NM4 and an input terminal to which the power-supply voltage VDD is input. The sixth resistor R6 may be a protection circuit to prevent damage to the fourth NMOS transistor NM4 due to electrostatic discharge ESD that may be introduced from the input terminal of the power-supply voltage VDD.

The voltage clamping circuit 350 may be connected to an output node of the second level shifter output voltage LS_OUT2 and the second output node VPOUT. The output node of the second level shifter output voltage LS_OUT2 may be connected to a gate of the sink transistor PM_SINK of the sink circuit 360. The second output node VPOUT may be connected to a source of the sink transistor PM_SINK. The voltage clamping circuit 350 may refer to a protection circuit that limits a voltage between two nodes so that a gate-source voltage of the sink transistor PM_SINK does not exceed a breakdown voltage of the sink transistor PM_SINK.

In the embodiment of FIG. 8, the voltage clamping circuit 350 is implemented with fourth to sixth diodes D4-D6 connected in series to each other, but the embodiments of the present disclosure are not limited thereto, and the number and type of diodes may be experimentally determined in consideration of the breakdown voltage of the sink transistor PM_SINK.

The sink circuit 360 may include a sink transistor PM_SINK that pulls down the voltage level of the second output node VPOUT in response to the second level shifter output voltage LS_OUT2 applied to the output node of the level shifter 310.

The sink transistor PM_SINK may be a PMOS transistor that is connected between a terminal for the power-supply voltage VDD and the second output node VPOUT and includes a gate to which the second level shifter output voltage LS_OUT2 is input. The sink transistor PM_SINK may be turned on in response to the second level shifter output voltage LS_OUT2 of the ground voltage VSS. Alternatively, if the sink transistor PM_SINK is implemented with an NMOS transistor, the sink transistor PM_SINK may be turned on in response to the power-supply voltage VDD. The turned-on sink transistor PM_SINK may output the ground voltage VSS to the second output node VPOUT. The sink transistor PM_SINK may be turned off in response to the second level shifter output voltage LS_OUT2 of the second charge pump voltage VPCP.

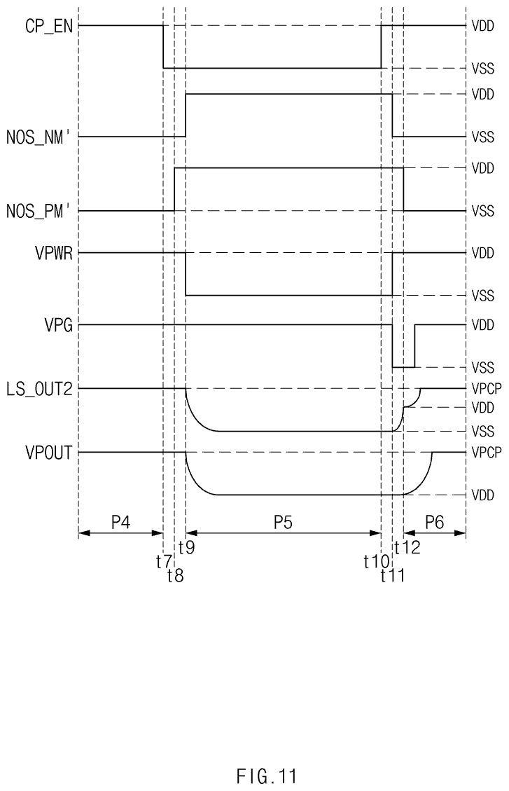

FIG. 11 is a timing diagram illustrating an operation of the pull-down circuit shown in FIG. 8 based on some embodiments of the present disclosure.

Referring to FIGS. 8 to 11, the charge pump enable signal CP_EN maintains the power-supply voltage VDD, transitions to the ground voltage VSS at a seventh time point t7, and transitions back to the power-supply voltage VDD at a tenth time point t10.

In a fourth section P4 located before the seventh time point t7, each of the charge pump enable signal CP_EN, the first non-overlapping signal NOS_PM, and the second non-overlapping signal NOS_NM may have the power-supply voltage VDD. Accordingly, the third PMOS transistor PM3 receiving the inverted first non-overlapping signal NOS_PM′ may be turned on, and the third NMOS transistor NM3 receiving the inverted second non-overlapping signal NOS_NM′ may be turned off.

The common node VPWR may receive the power-supply voltage VDD through the turned-on third PMOS transistor PM3. Accordingly, the fourth NMOS transistor NM4 may be turned off.

Since the first non-overlapping signal NOS_PM maintains the power-supply voltage VDD, i.e., the inverted first non-overlapping signal NOS_PM′ maintains the ground voltage VSS, the one-shot signal VPG may have the power-supply voltage VDD. In addition, due to the operation of the second charge pump circuit 40, the second output node VPOUT may have the second charge pump voltage VPCP. Accordingly, the fourth PMOS transistor PM4 may be turned on, so that the second level shifter output voltage LS_OUT2 may have the second charge pump voltage VPCP. As a result, the sink transistor PM_SINK may remain turned off.

When the charge pump enable signal CP_EN transitions from the power-supply voltage VDD to the ground voltage VSS at the seventh time point t7, the first non-overlapping signal NOS_PM may transition to the ground voltage VSS (i.e., the inverted first non-overlapping signal NOS_PM′ may transition to the power-supply voltage VDD) at an eighth time point t8 by the operation of the non-overlap signal generator 320, and the second non-overlapping signal NOS_NM may transition to the ground voltage VSS (i.e., the inverted second non-overlapping signal NOS_NM′ may transition to the power-supply voltage VDD) at a ninth time point t9.

At the eighth time point t8, when the first non-overlapping signal NOS_PM transitions to the ground voltage VSS (i.e., the inverted first non-overlapping signal NOS_PM′ transitions to the power-supply voltage VDD), the third PMOS transistor PM3 receiving the inverted first non-overlapping signal NOS_PM′ may be turned off so that the common node VNWR can be floated.

At the ninth time point t9, when the second non-overlapping signal NOS_NM transitions to the ground voltage VSS (i.e., the inverted second non-overlapping signal NOS_NM′ transitions to the power-supply voltage VDD), the third NMOS transistor NM3 receiving the inverted second non-overlapping signal NOS_NM′ may be turned on so that the common node VPWR may have the ground voltage VSS. Accordingly, the fourth NMOS transistor NM4 may be turned on and the second level shifter output voltage LS_OUT2 may transition to the ground voltage VSS. As a result, the sink transistor PM_SINK may be turned on and the voltage of the second output node VPOUT may transition (i.e., may be pulled down) to the power-supply voltage VDD.

In this time point, the one-shot signal VPG may maintain the power-supply voltage VDD, and the fourth PMOS transistor PM4 may be turned off. As a result, the second level shifter output voltage LS_OUT2 can maintain the ground voltage VSS.

In a fifth section P5, each signal and the voltage of each node can be maintained.

When the charge pump enable signal CP_EN transitions from the ground voltage VSS to the power-supply voltage VDD at the tenth time point t10, the first non-overlapping signal NOS_PM may transition to the power-supply voltage VDD at a twelfth time point t12 by the operation of the non-overlap signal generator 320, and the second non-overlapping signal NOS_NM may transition to the power-supply voltage VDD at an eleventh time point t11.

When the second non-overlapping signal NOS_NM transitions to the power-supply voltage VDD (i.e., the inverted second non-overlapping signal NOS_NM′ transitions to the ground voltage VSS) at the eleventh time point t11, the third NMOS transistor NM3 receiving the inverted second non-overlapping signal NOS_NM′ may be turned off so that the common node VPWR can be floated. In addition, as the second non-overlapping signal NOS_NM transitions to the power-supply voltage VDD (i.e., the inverted second non-overlapping signal NOS_NM′ transitions to the ground voltage VSS), the one-shot signal VPG may transition to the ground voltage VSS and the fourth PMOS transistor PM4 may be turned on, so that the second level shifter output voltage LS_OUT2 may transition to the power-supply voltage VDD acting as the voltage of the second output node VPOUT.

When the first non-overlapping signal NOS_PM transitions to the power-supply voltage VDD (i.e., the inverted first non-overlapping signal NOS_PM′ transitions to the ground voltage VSS) at the twelfth time point t12, the third PMOS transistor PM3 receiving the inverted first non-overlapping signal NOS_PM′ may be turned on so that the common node VPWR may have the power-supply voltage VDD. Accordingly, the fourth NMOS transistor NM4 may be turned off so that the second level shifter output voltage LS_OUT2 can be electrically isolated from the common node VPWR.

In addition, due to the operation of the second charge pump circuit 40, the second output node VPOUT may transition to the second charge pump voltage VPCP. Due to the turned-on fourth PMOS transistor PM4, the second level shifter output voltage LS_OUT2 may also transition to the second charge pump voltage VPCP in response to the voltage of the second output node VPOUT. As a result, the sink transistor PM_SINK may be turned off so that the second output node VPOUT can be electrically isolated from the power-supply voltage VDD.

According to the method of operating the pull-down circuit 300, the transistors PM3, NM3, PM4, NM4, PM_SINK included in the pull-down circuit 300 may operate stably within a range that does not exceed the breakdown voltage (e.g., 3.8V).

As is apparent from the above description, the pull-down circuit or the pull-up circuit based on some embodiments of the preset disclosure can stably operate within a range that does not deviate from a breakdown voltage of transistors included in the pull-down or pull-up circuit.

The embodiments of the present disclosure may provide a variety of effects capable of being directly or indirectly recognized.

Although a number of illustrative embodiments have been described, it should be understood that modifications and enhancements to the disclosed embodiments and other embodiments can be devised based on what is described and/or illustrated in the present disclosure. Therefore, the scope of the present disclosure should not be limited to the above-described embodiments but should include the equivalents thereof.

In the above-described embodiments, all operations may be selectively performed, or part of the operations may be omitted. In each embodiment, the operations are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

The embodiments of the present disclosure have been described in the drawings and specification. Although specific terminologies are used here, those are only to describe the embodiments of the present disclosure. Therefore, the present disclosure is not restricted to the above-described embodiments and many variations are possible within the scope of the present disclosure. It should be apparent to those skilled in the art that various modifications can be made on the basis of the technological scope of the present disclosure in addition to the embodiments disclosed herein. Furthermore, the embodiments may be combined to form additional embodiments.

What is claimed is:

1. A pull-up circuit comprising:
a sink circuit configured to pull up an output node of a charge pump circuit to a ground voltage, wherein the charge pump circuit generates a charge pump voltage less than the ground voltage; and
a level shifter configured to generate a level shifter output voltage that controls the sink circuit in response to a charge pump enable signal controlling the charge pump circuit, and to generate a one-shot signal that prevents floating of a node through which the level shifter output voltage is output.

2. The pull-up circuit according to claim 1, wherein the level shifter includes:
a non-overlap signal generator configured to generate a first non-overlapping signal and a second non-overlapping signal that are obtained by delaying the charge pump enable signal with different delay times.

3. The pull-up circuit according to claim 2, wherein the non-overlap signal generator includes:
a first path including a first NAND gate and a plurality of inverters, through which the second non-overlapping signal is output; and
a second path including a second NAND gate and multiple inverters through which the first non-overlapping signal is output,
wherein
the first NAND gate is configured to receive the charge pump enable signal; and
the second NAND gate is configured to receive an inverted signal of the charge pump enable signal.

4. The pull-up circuit according to claim 2, wherein the level shifter further includes
a voltage level controller including:
a first PMOS transistor configured to operate in response to the first non-overlapping signal; and
a first NMOS transistor configured to operate in response to the second non-overlapping signal.

5. The pull-up circuit according to claim 4, wherein:
the first PMOS transistor is configured to apply a power-supply voltage to a common node in response to the first non-overlapping signal of the ground voltage; and
the first NMOS transistor is configured to apply the ground voltage to the common node in response to the second non-overlapping signal of the power-supply voltage.

6. The pull-up circuit according to claim 5, wherein the level shifter further includes:
a second PMOS transistor connected between the common node and a node through which the level shifter output voltage is output, and configured to receive the ground voltage through a gate thereof.

7. The pull-up circuit according to claim 4, further comprising:
a one-shot signal generator configured to generate the one-shot signal based on a gate voltage of the first PMOS transistor.

8. The pull-up circuit according to claim 7, wherein the one-shot signal generator includes:
a one-shot inverter configured to invert the first non-overlapping signal acting as the gate voltage of the first PMOS transistor, and to output the inverted first non-overlapping signal; and
an AND gate configured to output the one-shot signal by performing an AND operation between the inverted first non-overlapping signal and the first non-overlapping signal.

9. The pull-up circuit according to claim 1, wherein the level shifter includes:
a second NMOS transistor connected between a node through which the level shifter output voltage is output and an output terminal of the charge pump circuit, and configured to receive the one-shot signal through a gate thereof.

10. The pull-up circuit according to claim 1, wherein the sink circuit includes a sink transistor, and
the level shifter includes
a voltage clamping circuit connected between a gate and a source of the sink transistor, and configured to limit a voltage level to be applied to the sink transistor.

11. A pull-down circuit comprising:
a sink circuit configured to pull down an output node of a charge pump circuit to a power-supply voltage, wherein the charge pump circuit generates a charge pump voltage greater than the power-supply voltage; and
a level shifter configured to generate a level shifter output voltage that controls the sink circuit in response to a charge pump enable signal controlling the charge pump circuit, and to generate a one-shot signal that prevents floating of a node through which the level shifter output voltage is output.

12. The pull-down circuit according to claim 11, wherein the level shifter includes
a non-overlap signal generator configured to generate a first non-overlapping signal and a second non-overlapping signal that are obtained by delaying the charge pump enable signal with different delay times.

13. The pull-down circuit according to claim 12, wherein the non-overlap signal generator includes:
a first path including a first NAND gate and a plurality of inverters through which the first non-overlapping signal is output; and
a second path including a second NAND gate and multiple inverters through which the second non-overlapping signal is output,
wherein
the first NAND gate is configured to receive the charge pump enable signal; and
the second NAND gate is configured to receive an inverted signal of the charge pump enable signal.

14. The pull-down circuit according to claim 12, wherein the level shifter further includes
a voltage level controller including:
a first PMOS transistor configured to operate in response to an inverted signal of the first non-overlapping signal; and
a first NMOS transistor configured to operate in response to an inverted signal of the second non-overlapping signal.

15. The pull-down circuit according to claim 14, wherein:
the first PMOS transistor is configured to apply the power-supply voltage to a common node in response to the first non-overlapping signal of the power-supply voltage; and
the first NMOS transistor is configured to apply a ground voltage to the common node in response to the second non-overlapping signal of the ground voltage.

16. The pull-down circuit according to claim 15, wherein the level shifter further includes:
a second NMOS transistor connected between the common node and a node through which the level shifter output voltage is output, and configured to receive the power-supply voltage through a gate thereof.

17. The pull-down circuit according to claim 14, further comprising:
a one-shot signal generator configured to generate the one-shot signal based on a gate voltage of the first NMOS transistor.

18. The pull-down circuit according to claim 17, wherein the one-shot signal generator includes:
a one-shot inverter configured to invert an inverted signal of the second non-overlapping signal acting as the gate voltage of the first NMOS transistor, and to output an inverted resultant signal; and
an OR gate configured to output the one-shot signal by performing an OR operation between the inversion resultant signal of the inverted second non-overlapping signal and an inverted signal of the second non-overlapping signal.

19. The pull-down circuit according to claim 11, wherein the level shifter includes
a second PMOS transistor connected between a node through which the level shifter output voltage is output and an output terminal of the charge pump circuit, and configured to receive the one-shot signal through a gate thereof.

20. The pull-down circuit according to claim 11, wherein the sink circuit includes a sink transistor, and
the level shifter includes
a voltage clamping circuit connected between a gate and a source of the sink transistor, and configured to limit a voltage level to be applied to the sink transistor.

21. A voltage supply circuit comprising:
a charge pump circuit configured to amplify a power-supply voltage or a ground voltage in response to a charge pump enable signal; and
a voltage adjusting circuit configured to generate a level shifter output voltage for controlling a sink circuit that pulls up or down an output node of the charge pump circuit in response to the charge pump enable signal, and to generate a one-shot signal for preventing floating of a node through which the level shifter output voltage is output.
